(19) United States
(12) Patent Application Publication
(10) Pub. No.: US 2025/0159801 A1
(43) Pub. Date: May 15, 2025

(54) FLEXIBLE CIRCUIT BOARD

(71) Applicant: CHIPBOND TECHNOLOGY CORPORATION, Hsinchu (TW)

(72) Inventors: Kung-Tzu Tu, Kaohsiung City (TW); Gwo-Shyan Sheu, Kaohsiung City (TW); Hsin-Hao Huang, Kaohsiung City (TW); Kuo-Liang Huang, Kaohsiung City (TW); Pei-Wen Wang, Taichung City (TW); Yu-Chen Ma, Kaohsiung City (TW)

(21) Appl. No.: 18/910,291

(22) Filed: Oct. 9, 2024

(30) Foreign Application Priority Data
Nov. 13, 2023 (TW) 112143589

(51) Int. Cl. H05K 1/03; H05K 1/18

(52) U.S. Cl. CPC H05K 1/0393; H05K 1/181; H05K 2201/09227; H05K 2201/09236; H05K 2201/10674

(57) ABSTRACT

A flexible circuit board includes a flexible substrate, a first circuit and a second circuit. The first circuit is provided on a first area defined on the top surface and includes a first input terminal and a first output terminal. The first input terminal is adjacent to a bottom side of the top surface and the first output terminal is adjacent to a top side of the top surface. The second circuit is provided on a second area defined on the top surface and includes a second input terminal and a second output terminal. The second input terminal is adjacent to the top side of the top surface and the second output terminal is adjacent to the bottom side of the top surface.

### CROSS-REFERENCE TO RELATED APPLICATIONS

This application claims priority to R.O.C patent application No. 112143589 filed Nov. 13, 2023, the disclosure of which is hereby incorporated by reference in its entirety.

### FIELD OF THE INVENTION

This invention relates to a flexible circuit board, and more particularly to circuit arrangement on a flexible substrate of a flexible circuit board.

### BACKGROUND OF THE INVENTION

Conventional flexible circuit boards mounted on rear side of electronic device can be bent to be connected to connection terminals on front side of electronic device, it is not necessary to reserve space on front side of electronic device for mounting the flexible circuit board so flexible circuit boards are feasible for borderless panels. The more the panel pixels, the more the output lines of the flexible circuit board. The output lines may be 20 times more than the input lines, that will cause wider output terminal and narrower input terminal on the flexible circuit board. Owing to conventional flexible circuit boards are manufactured in reel-to-reel system, tape width increment is required for the wider output terminal of the flexible circuit board, furthermore, two flexible circuit boards with wider output terminals may not be arranged on the tape side by side. In addition, the input terminal of the flexible circuit board is not varied usually, width increment of the output terminal of the flexible circuit board may cause most space on the flexible substrate to be idle and redundant, and uneconomic use of space may increase manufacture cost significantly.

### SUMMARY OF THE INVENTION

One object of the present invention is to provide two circuits arranged side-by-side reversely on a flexible substrate to efficiently use most space on the flexible substrate and avoid cost increment as circuit output terminal is too wide.

A flexible circuit board of the present invention includes a flexible substrate, a first circuit and a second circuit. A first area and a second area are defined on a top surface of the flexible substrate. The first and second circuits are arranged on the first and second areas, respectively. The first circuit includes a first input terminal and a first output terminal, the first input terminal is close to a bottom side of the top surface and the first output terminal is close to a top side of the top surface. The second circuit includes a second input terminal and a second output terminal, the second input terminal is close to the top side of the top surface and the second output terminal is close to the bottom side of the top surface.

The first and second circuits are designed to be side-by-side reversely on the flexible substrate, in other words, the narrower first input terminal of the first circuit and the wider second output terminal of the second circuit are arranged on the same side and the wider first output terminal of the first circuit and the narrower second input terminal of the second circuit are arranged on the same side. As a result, space on the flexible substrate can be used efficiently to lower manufacture cost of the flexible circuit board.

### BRIEF DESCRIPTION OF DRAWINGS

FIG. 1 is a top view diagram illustrating a flexible circuit board in accordance with a first embodiment of the present invention.

FIG. 2 is a top view diagram illustrating a flexible circuit board in accordance with a second embodiment of the present invention.

FIG. 3 is a top view diagram illustrating a flexible circuit board in accordance with a third embodiment of the present invention.

FIG. 4 is top view diagram illustrating a flexible circuit board in accordance with a fourth embodiment of the present invention.

### DETAILED DESCRIPTION OF THE INVENTION

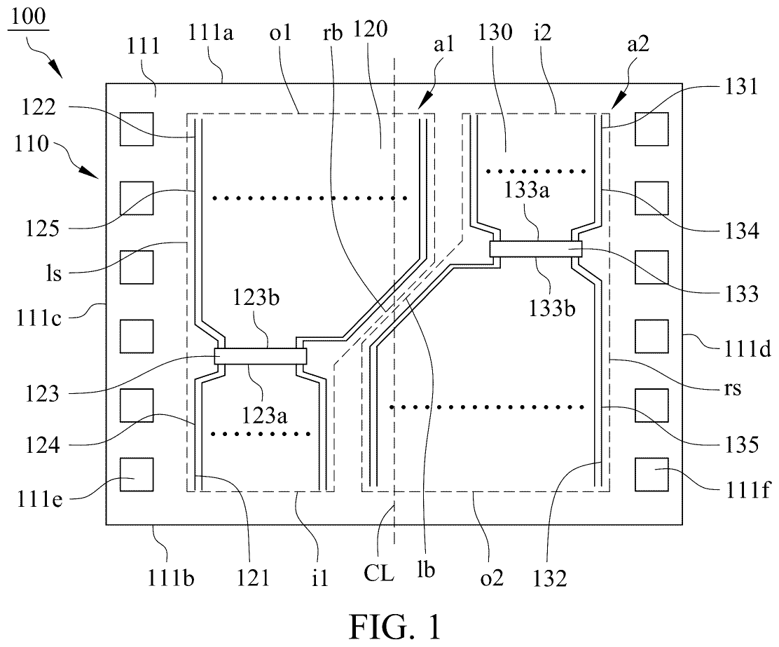

With reference to FIG. 1, a flexible circuit board 100 in accordance with a first embodiment of the present invention includes a flexible substrate 110, a first circuit 120 and a second circuit 130. The flexible substrate 110 has a top surface 111 with a top side 111a, a bottom side 111b, a left side 111c and a right side 111d as shown in drawings, and a first area a1 and a second area a2 are defined on the top surface 111. Before punching the flexible circuit board 100, the top side 111a of the top surface 111 is connected to the bottom side 111b of the top surface 111 of another flexible circuit board 100 on the reel-to-reel tape, and the bottom side 111b of the top surface 111 is connected to the top side 111a of the top surface 111 of another flexible circuit board 100. If the flexible circuit board 100 is small, the right side 111d of the top surface 111 can be connected to the left side 111c of the top surface 111 of another flexible circuit board 100, one flexible circuit board 100 is connected to three another flexible circuit boards 100 on the reel-to-reel tape.

The first area a1 and the second area a2 defined on the top surface 111 are side by side, the first area a1 is the left area enclosed by the dotted line shown in the drawings, and the second area a2 is the right area enclosed by another dotted line shown in the drawings. The first area a1 is located between the left side 111c of the top surface 111 and the second area a2, and the second area a2 is located between the right side 111d of the top surface 111 and the first area a1. The first area a1 and the second area a2 defined by the dotted lines will be cut to become actual circuit in subsequent process.

Preferably, there are first sprocket holes 111e and second sprocket holes 111f on the top surface 111. The first sprocket holes 111e are near and aligned along the left side 111c of the top surface 111, and they are located between the left side 111c and the first area a1. The second sprocket holes 111f are near and aligned along the right side 111d of the top surface 111, and they are located between the right side 111d and the second area a2. The first sprocket holes 111e and the second sprocket holes 111f are provided for reel-to-reel system to move the flexible circuit boards 100 on a tape.

The first circuit 120 is arranged on the first area a1 and includes a first input terminal i1, a first output terminal o1, first input lines 121, first output lines 122, a first chip 123, first transmission lines 124 and second transmission lines 125. The first input terminal i1 is close to the bottom side 111b of the top surface 111 and provided for receiving signals, and the first output terminal o1 is close to the top side 111a of the top surface 111 and provided for outputting signals. The first input lines 121, the first output lines 122, the first transmission lines 124 and the second transmission lines 125 are formed on the top surface 111 through the processes of copper plating and etching. The first chip 123 is mounted on the top surface 111 through flip-chip bonding and it is electrically connected to the first transmission lines 124 and the second transmission lines 125.

The first input lines 121 are located at and arranged along the first input terminal i1, and the first output lines 122 are located at and arranged along the first output terminal o1. The first chip 123 has a first input side 123a and a first output side 123b, the first input side 123a faces toward the first input terminal i1, and the first output side 123b faces toward the first output terminal o1. One end of each of the first transmission lines 124 is connected to the first input side 123a of the first chip 123, and the other end of each of the first transmission lines 124 is connected to one of the first input lines 121. The first input line 121 and the first transmission line 124 connected with each other are located at different positions of the same circuit line. The first input lines 121 are provided to connect with an external electronic device, e.g. a driver circuit board, and electrically connected to the first input side 123a of the first chip 123 via the first transmission lines 124. One end of each of the second transmission lines 125 is connected to the first output side 123b of the first chip 123, and the other end of each of the second transmission lines 125 is connected to one of the first output lines 122. The first output line 122 and the second transmission line 125 connected with each other are located at different positions of the same circuit line. The first output lines 122 are provided to connect with an external electronic device, e.g. a panel, and the first output lines 122 are electrically connected to the first output side 123b of the first chip 123 via the second transmission lines 125.

The second circuit 130 is provided on the second area a2 and includes a second input terminal i2, a second output terminal o2, second input lines 131, second output lines 132, a second chip 133, third transmission lines 134 and fourth transmission lines 135. The second input terminal i2 is adjacent to the top side 111a of the top surface 111, and the second output terminal o2 is adjacent to the bottom side 111b of the top surface 111. The second input terminal i2 and the second output terminal o2 of the second circuit 130 are signal receiving terminal and signal outputting terminal, respectively. The second input lines 131, the second output lines 132, the third transmission lines 134 and the fourth transmission lines 135 are formed on the top surface 111 after plating and etching copper layer. The second chip 133 is mounted on the top surface 111 through flip-chip bonding and is electrically connected to the third transmission lines 134 and the fourth transmission lines 135.

The second input lines 131 are located at and arranged along the second input terminal i2, and the second output lines 132 are located at and arranged along the second output terminal o2. A second input side 133a of the second chip 133 is directed toward the second input terminal i2, and a second output side 133b of the second chip 133 is directed toward the second output terminal o2. Both ends of each of the third transmission lines 134 are connected to the second input side 133a of the second chip 133 and one of the second input lines 131, respectively. The second input line 131 and the third transmission line 134 connected to one another are located at different positions of the same circuit line. The second input lines 131 can be connected with an external electronic device, e.g. a driver circuit board. The third transmission lines 134 are provided for electrical connection between the second input lines 131 and the second input side 133a of the second chip 133. Both ends of each of the fourth transmission lines 135 are connected to the second output side 133b of the second chip 133 and one of the second output lines 132, respectively. The second output line 132 and the fourth transmission line 135 connected with each other are located at different positions of the same circuit line. The second output lines 132 can be connected with an external electronic device, e.g. a panel, and they are electrically connected to the second output side 133b of the second chip 133 via the fourth transmission lines 135.

With reference to FIG. 1, in the first embodiment, the first output lines 122 of the first circuit 120 are more than the first input lines 121 of the first circuit 120, and the second output lines 132 of the second circuit 130 are more than the second input lines 131 of the second circuit 130. The first circuit 120 has a wide top narrow bottom design because the first output terminal o1 and the first input terminal i1 of the first circuit 120 face toward the top side 111a and the bottom side 111b of the top surface 111, respectively. In opposite, the second circuit 130 has a narrow top wide bottom design because the second output terminal o2 and the second input terminal i2 of the second circuit 130 face toward the bottom side 111b and the top side 111a of the top surface 111, respectively. The first circuit 120 and the second circuit 130 are reverse of each other so it is available to utilize the space on the top surface 111 efficiently and lower manufacture cost due to too much idle space on the flexible substrate 110.

In the first embodiment, the first output lines 122 are 1.4 to 20 times more than the first input lines 121, and the second output lines 132 are 1.4 to 20 times more than the second input lines 131. The bigger the quantity difference between the first output lines 122 and the first input lines 121, the more the efficient use of the space on the top surface 111 while the first circuit 120 and the second circuit 130 are arranged reversely.

In other embodiment(s), the first output lines 122 may be less than the first input lines 121, and the second output lines 132 may be less than the second input lines 131. Thus, the first circuit 120 has a narrow top with bottom design and the second circuit 130 has a wide top narrow bottom design, they can be also reverse of each other to utilize the space of the top surface 111 efficiently.

With reference to FIG. 1, the first circuit 120 and the second circuit 130 are the same circuits arranged on the flexible substrate 110 reversely, as a result, the first input lines 121 and the second input lines 131 have the same quantity number, the first output lines 122 and the second output lines 132 have the same quantity number, and the first area 1 and the second area a2 have the same contour.

With reference to FIG. 1, a right bent boundary rb of the first area a1 and a left bent boundary Ib of the second area a2 are side by side and near a center line CL of the top surface 111 such that the center area of the top surface 111 can be utilized efficiently. Preferably, the right bent boundary rb of the first area a1 is parallel to the left bent boundary Ib of the second area a2 for mostly utilizing the top surface 111 of the flexible substrate 110. Moreover, a left straight boundary Is of the first area a1 is close to the left side 111c of the top surface 111, and the first sprocket holes 111e are located between the left straight boundary Is of the first area a1 and the left side 111c of the top surface 111. Similarly, a right straight boundary rs of the second area a2 is adjacent to the right side 111d of the top surface 111, and the second sprocket holes 111f are located between the right straight boundary rs of the second area a2 and the right side 111d of the top surface 111. Thus, the first sprocket holes 111e and the second sprocket holes 111f can be aligned along the left straight boundary Is of the first area a1 and the right straight boundary rs of the second area a2, respectively, to efficiently utilize the space adjacent to the left side 111c and the right side 111d of the top surface 111.

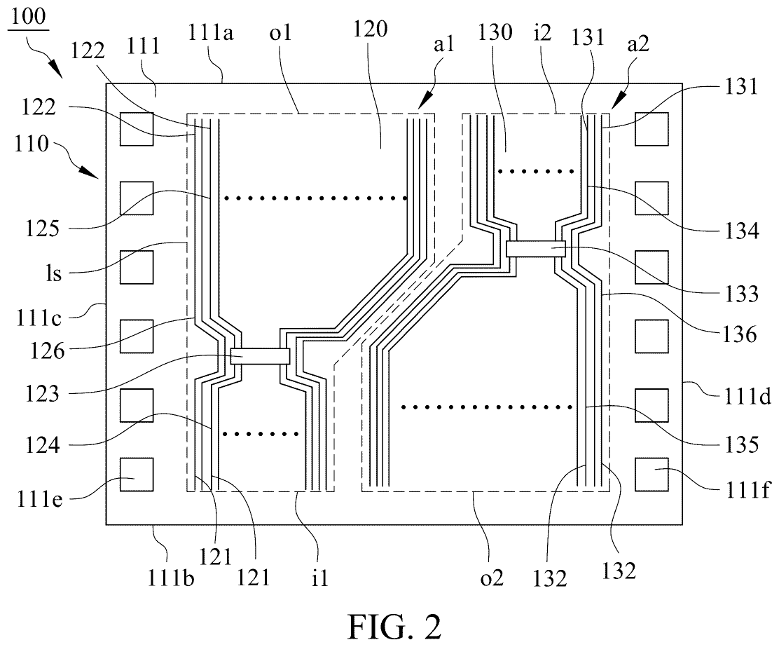

FIG. 2 shows a second embodiment of the present invention. Different to the first embodiment, the first circuit 120 further includes fifth transmission lines 126 and the second circuit 130 further includes sixth transmission lines 136 in the second embodiment. Both ends of each of the fifth transmission lines 126 are connected to one of the first input lines 121 and one of the first output lines 122, respectively. Both ends of each of the sixth transmission lines 136 are connected to one of the second input lines 131 and one of the second output lines 132, respectively. Signals transmitted through the first input line 121 and the first output line 122 connected with each of the fifth transmission lines 126 is not via the first chip 123, and signals transmitted through the second input line 131 and the second output line 132 connected with each of the sixth transmission lines 136 is not via the second chip 133.

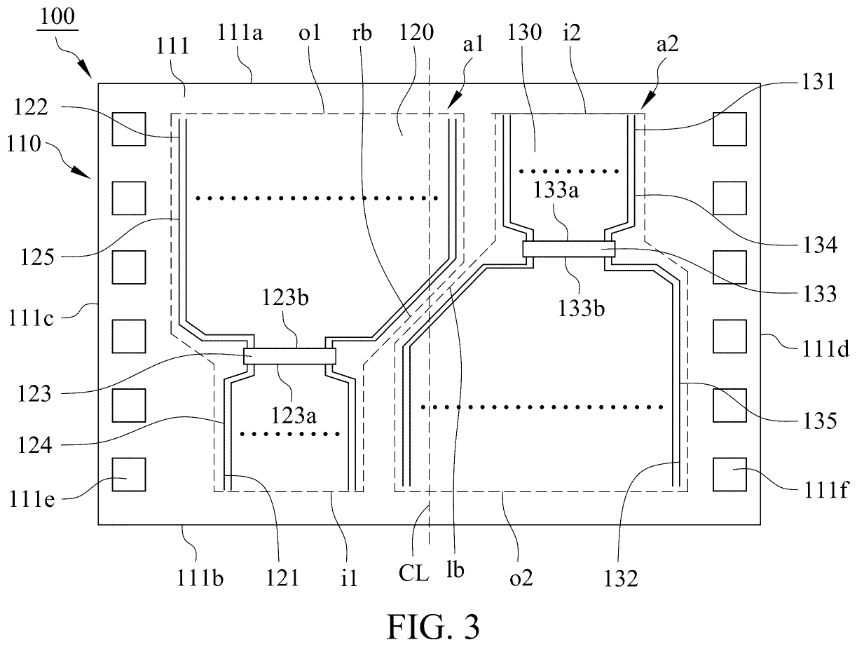

FIG. 3 is provided to illustrate a third embodiment of the present invention. The difference between the first and third embodiments is that the left boundary of the first area a1 and the right boundary of the second area a2 are bent (not straight) in the third embodiment. In the same way, input and output terminals of the first circuit 120 and the second circuit 130 are reverse in the third embodiment so as to utilize the top surface 111 of the flexible substrate 110 efficiently.

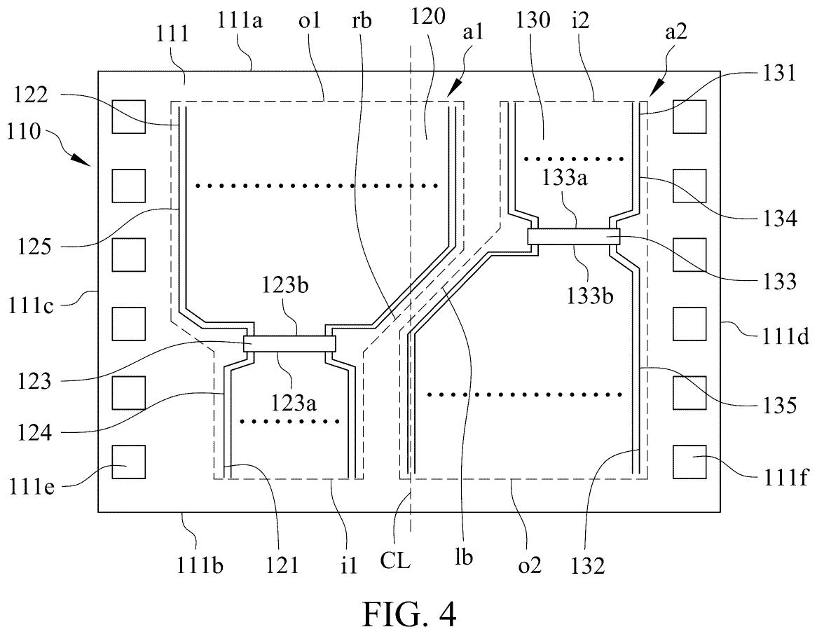

A fourth embodiment of the present invention is shown on FIG. 4, different to the first embodiment, the first circuit 120 and the second circuit 130 of the fourth embodiment are not the same circuit. The numbers of the first input lines 121 are not equal to that of the second input lines 131, and the numbers of the first output lines 122 are not equal to that of the second output lines 132 in the fourth embodiment. Although the first circuit 120 and the second circuit 130 have different designs with reverse input and output terminals, it is still able to utilize the top surface 111 of the flexible substrate 110 efficiently. In addition, circuits with different designs can be accommodated on the same flexible substrate 110 for more flexibility in use of tape. For example, a larger circuit and a smaller circuit can be designed on the flexible substrate 110 to improve space use.

The first circuit 120 and the second circuit 130 of the present invention are arranged side by side reversely on the flexible substrate 110 such that the narrower first input terminal i1 of the first circuit 120 and the wider second output terminal o2 of the second circuit 130 can be arranged on the same side, and the wider first output terminal o1 of the first circuit 120 and the narrower second input terminal i2 of the second circuit 130 can be arranged on the other side. Thus, it is able to use the space on the flexible substrate 110 efficiently to lower manufacture cost of the flexible circuit board 100.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. A flexible circuit board comprising:
a flexible substrate having a top surface, a first area and a second area are defined on the top surface;
a first circuit arranged on the first area and including a first input terminal and a first output terminal, wherein the first input terminal is adjacent to a bottom side of the top surface and the first output terminal is adjacent to a top side of the top surface; and
a second circuit arranged on the second area and including a second input terminal and a second output terminal, wherein the second input terminal is adjacent to the top side of the top surface and the second output terminal is adjacent to the bottom side of the top surface.

2. The flexible circuit board in accordance with claim 1, wherein the first circuit further includes a plurality of first input lines and a plurality of first output lines, the plurality of first input lines are located at and arranged along the first input terminal, the plurality of first output lines are located at and arranged along the first output terminal, the second circuit further includes a plurality of second input lines and a plurality of second output lines, the plurality of second input lines are located at and arranged along the second input terminal, the plurality of second output lines are located at and arranged along the second output terminal.

3. The flexible circuit board in accordance with claim 2, wherein numbers of the plurality of first and second input lines are equal, and numbers of the plurality of first and second output lines are equal.

4. The flexible circuit board in accordance with claim 3, wherein the plurality of first output lines are 1.4 to 20 times more than the plurality of first input lines, and the plurality of second output lines are 1.4 to 20 times more than the plurality of second input lines.

5. The flexible circuit board in accordance with claim 2, wherein the first circuit further includes a first chip, a plurality of first transmission lines and a plurality of second transmission lines, a first input side of the first chip is directed toward the first input terminal and a first output side of the first chip is directed toward the first output terminal, one end of each of the plurality of first transmission lines is connected to the first input side of the first chip and the other end of each of the plurality of first transmission lines is connected to one of the plurality of first input lines, one end of each of the plurality of second transmission lines is connected to the first output side of the first chip and the other end of each of the plurality of second transmission lines is connected to one of the plurality of first output lines, the second circuit further includes a second chip, a plurality of third transmission lines and a plurality of fourth transmission lines, a second input side of the second chip is directed toward the second input terminal and a second output side of the second chip is directed toward the second output terminal, one end of each of the plurality of third transmission lines is connected to the second input side of the second chip and the other end of each of the plurality of third transmission lines is connected to one of the plurality of second input lines, one end of each of the plurality of fourth transmission lines is connected to the second output side of the second chip and the other end of each of the plurality of fourth transmission lines is connected to one of the plurality of second output lines.

6. The flexible circuit board in accordance with claim 5, wherein the first circuit further includes a plurality of fifth transmission lines and the second circuit further includes a plurality of sixth transmission lines, one end of each of the plurality of fifth transmission lines is connected to one of the plurality of first input lines and the other end of the plurality of fifth transmission lines is connected to one of the plurality of first output lines, one end of each of the plurality of sixth transmission lines is connected to one of the plurality of second input lines and the other end of the plurality of sixth transmission lines is connected to one of the plurality of second output lines.

7. The flexible circuit board in accordance with claim 2, wherein numbers of the plurality of first and second input lines are not equal, and numbers of the plurality of first and second output lines are not equal.

8. The flexible circuit board in accordance with claim 1, wherein there are a plurality of first sprocket holes and a plurality of second sprocket holes on the top surface, the plurality of first sprocket holes are near and aligned along a left side of the top surface and the plurality of second sprocket holes are near and aligned along a right side of the top surface, the first area is located between the left side of the top surface and the second area, and the second area is located between the right side of the top surface and the first area, the plurality of first sprocket holes are located between the left side of the top surface and the first area, and the plurality of second sprocket holes are located between the right side of the top surface and the second area.

9. The flexible circuit board in accordance with claim 8, wherein a right bent boundary of the first area and a left bent boundary of the second area are side by side and adjacent to a center line of the top surface.

10. The flexible circuit board in accordance with claim 9, wherein a left straight boundary of the first area is adjacent to the left side of the top surface, the plurality of first sprocket holes are located between the left straight boundary of the first area and the left side of the top surface, a right straight boundary of the second area is adjacent to the right side of the top surface, and the plurality of second sprocket holes are located between the right straight boundary of the second area and the right side of the top surface.
